(19) United States
(12) Patent Application Publication
(10) Pub. No.: US 2013/0082756 A1
(43) Pub. Date: Apr. 4, 2013

(54) SIGNAL INPUT DEVICE OF DIGITAL-RF CONVERTER

(71) Applicants: Jang Hong CHOI, Daejeon (KR); Mun Yang PARK, Daejeon (KR); Hyun Ho BOO, Incheon (KR); Seon-Ho HAN, Daejeon (KR); Hyun Kyu YU, Daejeon (KR)

(72) Inventors: Jang Hong CHOI, Daejeon (KR); Mun Yang PARK, Daejeon (KR); Hyun Ho BOO, Incheon (KR); Seon-Ho HAN, Daejeon (KR); Hyun Kyu YU, Daejeon (KR)

(73) Assignee: ELECTRONICS AND TELECOMMUNICATIONS RESEARCH INSTITUTE, Daejeon (KR)

(21) Appl. No.: 13/614,262

(22) Filed: Sep. 13, 2012

(30) Foreign Application Priority Data
Oct. 4, 2011 (KR) 10-2011-0100878
May 16, 2012 (KR) 10-2012-0052201

(51) Int. Cl. H03K 3/84

(52) U.S. Cl. 327/164

(57) ABSTRACT

The present invention provides a signal input device of a digital-RF converter including: a phase-modulated signal input unit configured to input a phase-modulated carrier signal to an LO switch of a digital-RF converter; and a digital signal input unit configured to correct a digital signal to correspond to the phase-modulated carrier signal, and input the corrected digital signal to a data switch of the digital-RF converter.

### CROSS-REFERENCES TO RELATED APPLICATIONS

The present application claims priority under 35 U.S.0 119(a) to Korean Application Nos. 10-2011-0100878 and 10-2012-0052201, filed on Oct. 4, 2011 and May 16, 2012, in the Korean Intellectual Property Office, which are incorporated herein by reference in their entirety set forth in full.

### BACKGROUND

Exemplary embodiments relate to a signal input device of a digital-RF converter, and more particularly, to a signal input device of a digital-RF converter configured to prevent distortion of an output signal generated by a transient response of a digital input signal.

FIG. 1 is a block configuration diagram showing a transmitter using a digital-RF converter of the related art, FIG. 2 is a circuit diagram briefly illustrating an M-bit digital-RF converter, and FIG. 3 is a circuit diagram of a 1 bit digital-RF converter, illustrating that a distortion signal is generated in an output signal by the pattern of a digital input signal.

In a transmitter using a digital-RF converter of the related art, I- and Q-digital signals at the baseband increase in sampling frequency through an interpolator 10 and lose the harmonic component through a digital filter. A local oscillator 50 generates a local oscillation signal and a quadrature oscillation signal generator 60 generates an I-oscillation signal LO-I and a Q-oscillation signal LO_Q from the local oscillation signal and transmits the I-oscillation signal LO-I and Q-oscillation signal LO_Q to a digital-RF converters 30 and 40.

The digital-RF converters 30 and 40 modulate a digital signal into an RF signal in accordance with the I-oscillation signal LO-I and Q-oscillation signal LO_Q.

A summer 70 sums up the RF signals modulated by the digital-RF converters 30 and 40.

The RF signal summed up by the summer 70 is amplified by a power amplifier (PA) 80, band-passed through a band pass filter (BPF) 90, and transmitted to an antenna 95.

In the transmitter using the digital-RF converters 30 and 40, M-bit digital-RF converters are commonly used as the digital-RF converters 30 and 40, as illustrated in FIG. 2.

In the digital-RF converters 30 and 40, ideally, a digital input signal is input in an ideal square wave and a distortion signal is not generated in the output by an ideal switching operation.

However, actually, as indicated by a dotted line in FIG. 3, an input signal shows a transient response in a transient section where the signal state changes (0->1 or 1->0). The output signal also shows a transient response in the transient response section of the input signal by the transient response. As a result, there was a problem in that since the output signal depends on the pattern of the input signal, a transient response is shown in the output signal by the transient response of the input signal.

There was a problem in that the distortion of the output signal due to the transient response of the input signal acts as noise and deteriorates the signal-to-noise ratio characteristics.

As Background Art related with the present invention, there is U.S. patent Registration Ser. No. 06/937,848 (2005 Aug. 30), titled ‘Method and device for digital-to-RF conversion’.

### SUMMARY

An exemplary embodiment of the present invention is directed to provide a signal input device of a digital-RF converter having a signal-to-noise ratio improved by generating noise, which is generated by a transient response of an input signal, at a specific frequency or randomly.

An exemplary embodiment of the present invention provides a signal input device of a digital-RF converter which includes: a phase-modulated signal input unit configured to input a phase-modulated carrier signal to an LO switch of a digital-RF converter; and a digital signal input unit configured to correct a digital signal to correspond to the phase-modulated carrier signal, and input the corrected digital signal to a data switch of the digital-RF converter.

The phase-modulated signal input unit includes an LO phase modulator configured to generate the phase-modulated carrier signal by modulating the phase of a carrier signal through a random pulse input from a pulse stream generator generating a random pulse by receiving a digital clock.

The phase-modulated signal input unit includes an LO phase modulator configured to generate the phase-modulated carrier signal by modulating the phase of a carrier signal through a square wave having a constant period input from a pulse stream generator generating a square wave having a constant period by receiving a digital clock.

The digital signal input unit includes a logic circuit unit configured to perform XNOR (Exclusive NOR) on raw data and the random pulse input from the pulse stream generator generating a random pulse by receiving a digital system clock.

The digital signal input unit includes a logic circuit unit configured to perform XNOR (Exclusive NOR) on raw data and the square wave having a constant period input from the pulse stream generator generating a square wave having a constant period by receiving a digital system clock.

The phase-modulated carrier signal is shared by a plurality of digital-RF converters.

According to the present invention, as the frequency component of a distortion signal depending on an input signal is not positioned at a signal band, but positioned at a specific frequency, for example, a clock frequency, signal-to-noise ratio is improved and leakage of a carrier signal is reduced.

### BRIEF DESCRIPTION OF THE DRAWINGS

The above and other aspects, features and other advantages will be more clearly understood from the following detailed description taken in conjunction with the accompanying drawings, in which:

FIG. 1 is a block configuration diagram showing a transmitter using a digital-RF converter of the related art;

FIG. 2 is a circuit diagram briefly illustrating an M-bit digital-RF converter;

FIG. 3 is a circuit diagram of a 1 bit digital-RF converter, illustrating that a distortion signal is generated in an output signal by the pattern of a digital input signal;

FIG. 4 is a block configuration diagram of a signal input device of a digital-RF converter in accordance with an exemplary embodiment of the present invention;

FIG. 5 is a diagram illustrating periodrization of a distortion signal of an output generated by the pattern of a digital input signal that is input to the digital-RF converter in accordance with an exemplary embodiment of the present invention; and

FIG. 6 is a configuration diagram when M unit-weighted digital-RF converters are combined with a transmitter in accordance with an exemplary embodiment of the present invention.

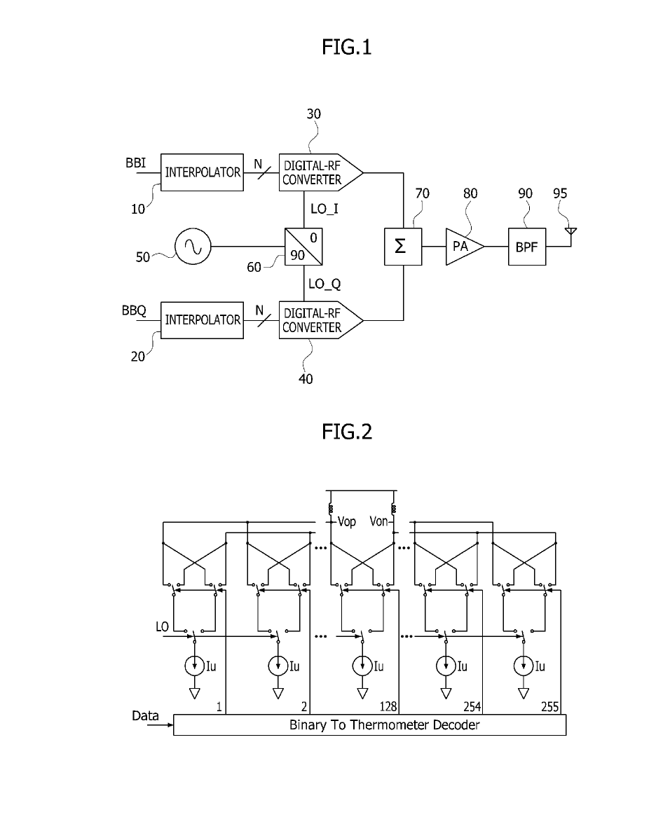

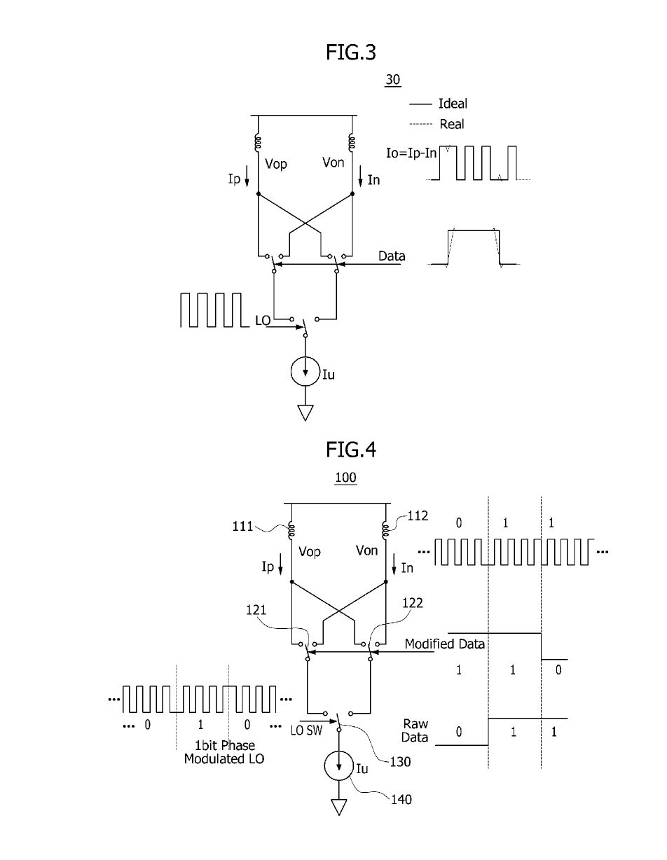

### DESCRIPTION OF SPECIFIC EMBODIMENTS

Hereinafter, a signal input device of a digital-RF converter according to an exemplary embodiment of the present invention will be described in detail with reference to the accompanying drawings. The thicknesses of lines or sizes of components illustrated in the drawings may be exaggerated for the clarity and convenience of the following description. Further, the terminologies described below are terminologies determined in consideration of the functions in the present invention and may be construed in different ways by the intention of users and operators. Therefore, the definitions of the thereof should be construed based on the contents throughout the specification.

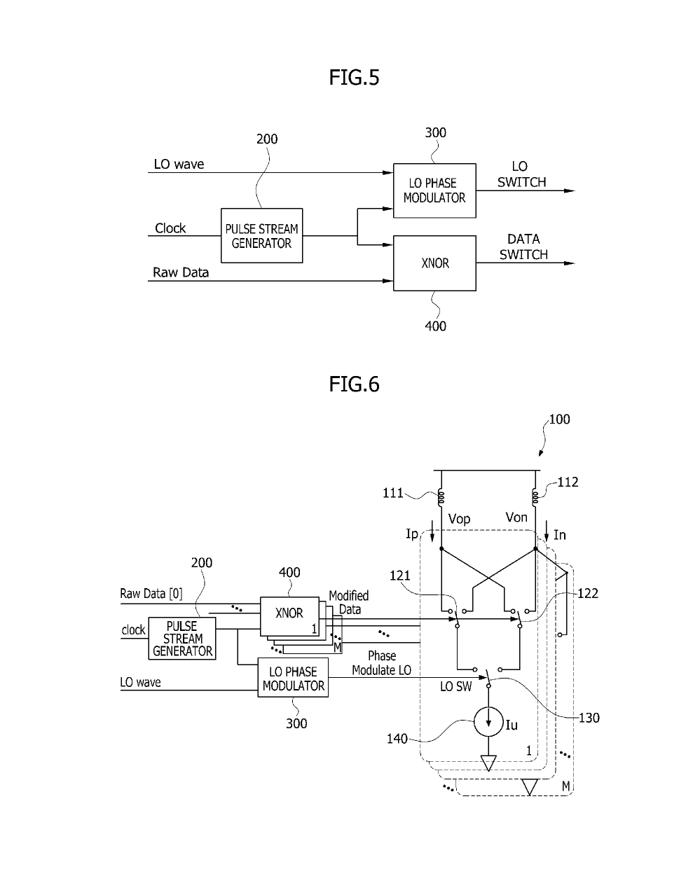

FIG. 4 is a block configuration diagram of a signal input device of a digital-RF converter in accordance with an exemplary embodiment of the present invention, FIG. 5 is a diagram illustrating periodrization of a distortion signal of an output generated by the pattern of a digital input signal that is input to the digital-RF converter in accordance with an exemplary embodiment of the present invention, and FIG. 6 is a configuration diagram when M unit-weighted digital-RF converters are combined with a transmitter in accordance with an exemplary embodiment of the present invention.

A signal input device of a digital-RF converter according to an exemplary embodiment of the present invention includes a phase-modulated signal input unit and a digital signal input unit, in which the phase-modulated signal input unit a random pulse or a square wave having a constant period from a pulse stream generator 200 and inputs a phase-modulated carrier signal to an LO switch of the digital-RF converter, and the digital signal input unit corrects a digital signal to correspond to the phase-modulated carrier signal and inputs the corrected digital signal to a data switch of the digital-RF converter.

The phase-modulated signal input unit includes an LO phase converter 300 and the digital signal input unit includes a logic circuit unit 400.

First, the pulse stream generator 200 is shared with the phase-modulated signal input unit and the digital signal input unit and inputs a random pulse of a square wave having a constant period to the pulse stream generator 200 and the logic circuit unit 400. However, the pulse stream generator 200 is not necessarily shared and the scope of the present invention may include that the pulse stream generator 200 is separately provided for the stream generator 200 and the logic circuit unit 400.

The pulse stream generator 200 includes an LO phase modulator 300 and a logic circuit unit 400.

The pulse stream generator 200 receives a digital clock Clock of a digital system (not illustrated) and generates and inputs a random pulse or a square wave having a constant period to the LO phase modulator 300 and the logic circuit unit 400.

The LO phase modulator 300 receives a carrier signal LO Wave of a local oscillator (not illustrated) and an output of the pulse stream generator 200 and switching the carrier signal and the output of the pulse stream generator 200, thereby modulating the phase of the carrier signal, and inputs the phase-modulated carrier signal Phase Modulated LO to the LO switch 130 of the digital-RF converter 100.

In this process, the phase of the carrier signal of the local oscillator is modulated by the LO phase modulator 300, so that the digital input signal Raw Data should be changed to correspond to the phase modulation of the carrier signal.

The logic circuit unit 400 corrects the digital input signal by performing XNOR (Exclusive NOR) on the output of the pulse stream generator 200 and the digital input signal and inputs the corrected digital input signal Modified data to data switches 121 and 122 of the digital-RF converter 100.

The digital-RF converter 100 generates a modulation signal in accordance with the switching operations of the LO switch 130 and the data switch 121 and 122, when a phase-modulated carrier signal is input from the LO phase modulator 300 and the corrected digital input signal is input from the logic circuit unit 400. In this process, the LO switch 130 is operated by the phase-modulated carrier signal and the data switches 121 and 122 are operated in accordance with the corrected digital input signal, and accordingly, the signal-to-noise ratio is improved by making noise, which is generated by a transient response of the input signal, generated at a specific frequency or randomly.

The digital-RF converter 100, as illustrated in FIG. 4, a current source 140, the LO switch 130, a pair of data switches 121 and 122, and a pair of inductive loads 111 and 112.

The data switches 121 and 122 operate as differential switches in accordance with the digital input signal corrected by the logic circuit unit 400, using positive output terminals and negative output terminals that are connected to an RF load (not illustrated) in a differential type. The positive output terminals and the negative output terminals are connected to the RF load through the inductive loads 111 and 1112, and one terminal of each of the data switches 121 and 122 is connected to the positive output terminal and the other terminal is connected to the negative output terminal. The data switches 121 and 122 operate in accordance with the corrected digital input signal input from the logic circuit unit 400.

The other terminals of the data switches 121 and 122 are selectively connected with the current source 130 by the operation of the LO switch 130.

The LO switch 130 operates in accordance with the phase-modulated carrier signal and connects any one of the pair of switches 121 and 122 with a current source 140.

As described above, as the LO switch 130 operates and the current source 130 is connected with any one of the pair of data switches 121 and 122 in accordance with the carrier signal with the phase modulated by the LO phase modulator 300 and the data switches 121 and 122 are switched such that the RF load and the current source 140 are connected, the digital input signal is upward-converted into an analog RF signal.

The operation process of the signal input device of the digital-RF converter according to an exemplary embodiment of the present invention will be described in detail.

The pulse stream generator 200 receives a digital clock of a digital system and generates and inputs a random pulse or a square wave having a constant period to the LO phase modulator 300 and the logic circuit unit 400.

The LO phase modulator 300 is operated by receiving a random pulse or a square wave having a constant period from the pulse stream generator 200 and inputs a pulse stream of 0 and 1, which are repeated, to the LO switch 130 of the digital-RF converter 100 by modulating the phase of the carrier signal of the local oscillator.

When receiving a random pulse of a square wave having a constant period from the pulse stream generator 200, the logic circuit unit 400 performs XNOR with a digital input signal and inputs the resultant to the data switches 121 and 122 of the digital-RF converter 100. Accordingly, the data switches 121 and 122 of the digital-RF converter operate and generate a current path of the digital-RF converter 100.

That is, the LO switch 130 is switched by using the phase-modulated carrier signal such that the frequency component of a distortion signal depending on the input signal is positioned not at the signal band, but at a digital clock frequency. Further, when a random pulse is generated from the pulse stream generator 200, the frequency components of the distortion signal of the output spectrum are uniformly distributed at the frequency band, so that the characteristics of the signal-to-noise ratio are improved and the output power of the carrier signal is reduced, and thus, it is possible to decrease carrier signal leakage.

Further, when the frequency component of the distortion signal generated by the digital input signal is not positioned at the signal band, but concentrated at a specific frequency, for example, the sampling frequency of data, the frequency component exists far from the signal band, so that the frequency component may be easily removed through a high-frequency filter (not illustrated).

Meanwhile, although a 1 bit digital-RF converter was exemplified in the exemplary embodiment described above, the actual digital-RF converter is composed of a plurality of bits to reduce quantization noise. This is illustrated in FIG. 6.

Referring to FIG. 6, the phase-modulated carrier signal is shared by the digital-RF converters 100 and input to the LO switches 130 of the digital-RF converters 100, and the corrected digital input signal is input to the data switches 121 and 122 of each digital-RF converter 100 through each logic circuit unit 400.

Although the present invention has been described with reference to the exemplary embodiments illustrated in the drawings, those are only examples and may be changed and modified into other equivalent exemplary embodiments from the present invention by those skilled in the art. Therefore, the technical protection range of the present invention should be determined by the following claims.

What is claimed is:

1. A signal input device of a digital-RF converter comprising:
a phase-modulated signal input unit configured to input a phase-modulated carrier signal to an LO switch of a digital-RF converter; and
a digital signal input unit configured to correct a digital signal to correspond to the phase-modulated carrier signal, and input the corrected digital signal to a data switch of the digital-RF converter.

2. The signal input device of claim 1, wherein the phase-modulated signal input unit includes an LO phase modulator configured to generate the phase-modulated carrier signal by modulating the phase of a carrier signal through a random pulse input from a pulse stream generator generating a random pulse by receiving a digital clock.

3. The signal input device of claim 1, wherein the phase-modulated signal input unit includes an LO phase modulator configured to generate the phase-modulated carrier signal by modulating the phase of a carrier signal through a square wave having a constant period input from a pulse stream generator generating a square wave having a constant period by receiving a digital clock.

4. The signal input device of claim 1, wherein the digital signal input unit includes a logic circuit unit configured to perform XNOR (Exclusive NOR) on raw data and the random pulse input from the pulse stream generator generating a random pulse by receiving a digital system clock.

5. The signal input device of claim 1, wherein the digital signal input unit includes a logic circuit unit configured to perform XNOR (Exclusive NOR) on raw data and the square wave having a constant period input from the pulse stream generator generating a square wave having a constant period by receiving a digital system clock.

6. The signal input device of claim 1, wherein the phase-modulated carrier signal is shared by a plurality of digital-RF converters.
